(19) United States
(12) Patent Application Publication
(10) Pub. No.: US 2024/0067872 A1
(43) Pub. Date: Feb. 29, 2024

(54) QUANTUM DOT FILM AND PREPARATION METHOD THEREFOR, PHOTOELECTRIC DEVICE, DISPLAY APPARATUS AND PREPARATION METHOD FOR QUANTUM DOT LIGHT-EMITTING DEVICE

(71) Applicants: Beijing BOE Technology Development Co., Ltd., Beijing (CN); BOE Technology Group Co., Ltd., Beijing (CN)

(72) Inventor: Haowei WANG, Beijing (CN)

(21) Appl. No.: 18/272,354

(22) PCT Filed: Jul. 20, 2022
(86) PCT No.: PCT/CN2022/106676

§ 371 Date: Jul. 14, 2023

(30) Foreign Application Priority Data
Jul. 27, 2021 (CN) 202110852180.6

(51) Int. Cl. C09K 11/02; H10K 50/115; H10K 71/12

(52) U.S. Cl. CPC C09K 11/025; H10K 50/115; H10K 71/12; B82Y 20/00

(57) ABSTRACT

A quantum dot film and a preparation method therefor, a photoelectric device, a display apparatus, and a preparation method for a quantum dot light-emitting device. The quantum dot film is formed by quantum dots containing a ligand, and the ligand is a halogen ion. The preparation method for the quantum dot film includes: S100: preparing an initial quantum dot film by using quantum dots containing an oil-soluble ligand; and S200: using a solid-state ligand exchange method to perform ligand exchange on the oil-soluble ligand on the surface of the initial quantum dot film by using an organic salt of a halogen, such that the oil-soluble ligand on the surface of the quantum dot film is exchanged into the halogen ion.

### CROSS-REFERENCE TO RELATED APPLICATIONS

This application is a national stage application of PCT Application No. PCT/CN2022/106676, which is filed on Jul. 20, 2022, and claims the priority of Chinese Patent Application No. 202110852180.6 filed with the CNIPA on Jul. 27, 2021 and entitled “Quantum Dot Film and Preparation Method Therefor, Photoelectric Device, Display Apparatus and Preparation Method for Quantum Dot Light-emitting Device”, the contents of which should be construed as being incorporated herein by reference.

### TECHNICAL FIELD

Embodiments of the present disclosure relate to, but are not limited to, the field of display technology, and particularly to a quantum dot film and a preparation method therefor, a photoelectric device, a display apparatus and a preparation method for a quantum dot light-emitting device.

### BACKGROUND

Colloidal quantum dots have great application potential in high color quality display because of their excellent characteristics such as high quantum efficiency, narrow excitation spectrum, unique size-dependent excitation spectrum and good solution processing compatibility. A quantum dot light-emitting diode (QLED) is a quantum dot-based electroluminescent device, which uses quantum dots as a light-emitting layer, has great superiority compared with an organic light-emitting diode, and is expected to become the core of next-generation display technology. In recent years, with the continuous development of quantum dot electroluminescence technology, a small number of relevant display products have been put into the market, but there is still a long way to go before mass production, mainly because the device efficiency is still low and the service life also needs to be continuously improved. An important determinant factor of device performance lies in the performance of light-emitting materials, and improving the light-emitting performance of materials is of great significance for the subsequent improvement in device light-emitting performance.

Quantum dot materials can emit fluorescence under light irradiation, and the light-emitting efficiency depends largely on modification of surface ligands in addition to the quality of a quantum dot core-shell structure. Directly synthesized quantum dot materials often cannot emit light due to the presence of a large number of defects on the surface, or have relatively low efficiency and need to be coated with ligand materials to increase the light-emitting efficiency thereof. Thus, the quality and quantity of ligands have great influence on the light-emitting performance of quantum dots. In addition, in the manufacturing of a device, the defects in quantum dot materials will also cause defective light emission, reduce color purity of light emission of the device. In this respect, it is also very important to reduce the defects of quantum dots.

### SUMMARY

The following is a summary of subject matters described herein in detail. The summary is not intended to limit the protection scope of the present disclosure.

An embodiment of the present disclosure provides a quantum dot film formed by quantum dots containing a ligand, the ligand being a halogen ion.

In an exemplary embodiment, the ligand may be selected from any one or more of I⁻, Br⁻, and Cl⁻.

In an exemplary embodiment, the ligand may be selected from two or three of I⁻, Br⁻ and Cl⁻.

In an exemplary embodiment, the quantum dot may be selected from any one or more of CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaNk, ZnTe, Si, Ge and C.

An embodiment of the present disclosure further provides a photoelectric device, which may be any one of a quantum dot light-emitting device, a photodetector, a photovoltaic device, a light-responsive transistor and a field-responsive transistor, the photoelectric device including the quantum dot film described above.

In an exemplary embodiment, the photoelectric device is a quantum dot light-emitting device, including an anode, a cathode, and a quantum dot light-emitting layer disposed between the anode and the cathode, the quantum dot light-emitting layer being the quantum dot film described above. An embodiment of the present disclosure further provides a display apparatus, including a plurality of quantum dot light-emitting devices, a light-emitting layer of the quantum dot light-emitting device being the quantum dot film described above.

An embodiment of the present disclosure further provides a preparation method for a quantum dot film, including:
S100: preparing an initial quantum dot film by using quantum dots containing an oil-soluble ligand; and
S200: using a solid-state ligand exchange method to perform ligand exchange on the oil-soluble ligand on a surface of the initial quantum dot film by using an organic salt of a halogen, such that the oil-soluble ligand on the surface of the quantum dot film is exchanged into a halogen ion, and subjecting the organic salt of a halogen to a coordination reaction with an unoccupied defect site on the surface of the quantum dot to obtain a quantum dot film with a surface ligand being a halogen ion.

In an exemplary embodiment, the step S200 may include:
S201: performing ligand exchange on the oil-soluble ligand on the surface of the initial quantum dot film by using an organic salt of a first halogen, such that the oil-soluble ligand on the surface of the quantum dot film is exchanged into a first halogen ion, and subjecting the organic salt of a first halogen to a coordination reaction with an unoccupied defect site on the surface of the quantum dot to obtain a first quantum dot film with a surface ligand being a first halogen ion; and
S202: subjecting an organic salt of a second halogen to a coordination reaction with an unoccupied defect site on a surface of the first quantum dot film to obtain a second quantum dot film with surface ligands being a first halogen ion and a second halogen ion;
wherein a particle size of the first halogen ion is larger than that of the second halogen ion.

In an exemplary embodiment, the step S200 may further include: after the step S202,
S203: subjecting an organic salt of a third halogen to a coordination reaction with an unoccupied defect site on a surface of the second quantum dot film to obtain a third quantum dot film with surface ligands being a first halogen ion, a second halogen ion and a third halogen ion;
wherein a particle size of the second halogen ion is larger than that of the third halogen ion.
In an exemplary embodiment, the first halogen ion may be I⁻, the second halogen ion may be Br⁻, and the third halogen ion may be Cl⁻.

In an exemplary embodiment, the ligand exchange or the coordination reaction may include:
dissolving an organic salt of a halogen in a solvent to prepare an organic salt solution of a halogen;
dropping the organic salt solution of a halogen onto a quantum dot film to be subjected to ligand exchange or a coordination reaction, standing for a first period of time and then spinning dry; or soaking the quantum dot film to be subjected to ligand exchange or a coordination reaction in the organic salt solution of a halogen, standing for a second period of time, and then taking the quantum dot film out from the organic salt solution of a halogen and spinning dry; and
cleaning a surface of the spinning-dried quantum film with a same solvent as that used for formulating the organic salt solution of a halogen.

In an exemplary embodiment, a concentration of the organic salt solution of a halogen may be 2 mg/mL to 50 mg/ml.

In an exemplary embodiment, the organic salt of a halogen may be selected from any one or more of tetrabutyl ammonium halide, tetrapropyl ammonium halide, and tetrapentyl ammonium halide; and the halogen in the organic salt of a halogen is I, Br or Cl.

In an exemplary embodiment, the solvent may be any one or more of deionized water, acetonitrile, methanol and ethanol.

In an exemplary embodiment, the first period of time may be 30 seconds to 90 seconds.

In an exemplary embodiment, the second period of time may be 10 seconds to 120 seconds.

An embodiment of the present disclosure further provides a preparation method for a quantum dot light-emitting device, including:
forming a first electrode;
forming a quantum dot light-emitting layer, the quantum dot light-emitting layer being a quantum dot film formed by quantum dots containing a ligand, the ligand being a halogen ion; and
forming a second electrode.

In an exemplary embodiment, the forming a quantum dot light-emitting layer may include:
S100: preparing an initial quantum dot film by using quantum dots containing an oil-soluble ligand; and
S200: using a solid-state ligand exchange method to perform ligand exchange on the oil-soluble ligand on a surface of the initial quantum dot film by using an organic salt of a halogen, such that the oil-soluble ligand on the surface of the quantum dot film is exchanged into a halogen ion, and subjecting the organic salt of a halogen to a coordination reaction with an unoccupied defect site on the surface of the quantum dot to obtain a quantum dot film with a surface ligand being a halogen ion, thus obtaining a quantum dot light-emitting layer.

In an exemplary embodiment, the step S200 may include:
S201: performing ligand exchange on the oil-soluble ligand on the surface of the initial quantum dot film by using an organic salt of a first halogen, such that the oil-soluble ligand on the surface of the quantum dot film is exchanged into a first halogen ion, and subjecting the organic salt of a first halogen to a coordination reaction with an unoccupied defect site on the surface of the quantum dot to obtain a first quantum dot film with a surface ligand being a first halogen ion; and
S202: subjecting an organic salt of a second halogen to a coordination reaction with an unoccupied defect site on a surface of the first quantum dot film to obtain a second quantum dot film with surface ligands being a first halogen ion and a second halogen ion;
wherein a particle size of the first halogen ion is larger than that of the second halogen ion.

In an exemplary embodiment, the step S200 may further include: after the step S202,
S203: subjecting an organic salt of a third halogen to a coordination reaction with an unoccupied defect site on a surface of the second quantum dot film to obtain a third quantum dot film with surface ligands being a first halogen ion, a second halogen ion and a third halogen ion;
wherein a particle size of the second halogen ion is larger than that of the third halogen ion.

In an exemplary embodiment, the first halogen ion may be I⁻, the second halogen ion may be Br⁻, and the third halogen ion may be Cl⁻.

In an exemplary embodiment, the ligand exchange or the coordination reaction may include:
dissolving an organic salt of a halogen in a solvent to prepare an organic salt solution of a halogen;
dropping the organic salt solution of a halogen onto a quantum dot film to be subjected to ligand exchange or a coordination reaction, standing for a first period of time and then spinning dry; or soaking the quantum dot film to be subjected to ligand exchange or a coordination reaction in the organic salt solution of a halogen, standing for a second period of time, and then taking the quantum dot film out from the organic salt solution of a halogen and spinning dry; and
cleaning a surface of the spinning-dried quantum film with a same solvent as that used for formulating the organic salt solution of a halogen.

In an exemplary embodiment, a concentration of the organic salt solution of a halogen may be 2 mg/mL to 50 mg/ml.

In an exemplary embodiment, the organic salt of a halogen may be selected from any one or more of tetrabutyl ammonium halide, tetrapropyl ammonium halide, and tetrapentyl ammonium halide; and the halogen in the organic salt of a halogen is I, Br or Cl.

In an exemplary embodiment, the solvent may be any one or more of deionized water, acetonitrile, methanol and ethanol.

In an exemplary embodiment, the first period of time may be 30 seconds to 90 seconds.

In an exemplary embodiment, the second period of time may be 10 seconds to 120 seconds.

In an exemplary embodiment, the quantum dot may be selected from any one or more of CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaNk, ZnTe, Si, Ge and C; and the initial quantum dot film may be formed by spin coating, evaporation or inkjet printing.

In an exemplary embodiment, the first electrode is an anode and the second electrode is a cathode;
after forming the first electrode and before forming a quantum dot light-emitting layer, the preparation method may further include: forming a hole injection layer and a hole transport layer on the first electrode sequentially;
the forming a quantum dot light-emitting layer includes: forming the quantum dot light-emitting layer on the hole transport layer;
after forming the quantum dot light-emitting layer and before forming a second electrode, the preparation method may further include: forming an electron transport layer on the quantum dot light-emitting layer; and
the forming the second electrode includes: forming the second electrode on the electron transport layer.

In an exemplary embodiment, the first electrode is a cathode and the second electrode is an anode;
after forming the first electrode and before forming a quantum dot light-emitting layer, the preparation method may further include: forming an electron transport layer on the first electrode;
the forming a quantum dot light-emitting layer includes: forming the quantum dot light-emitting layer on the electron transport layer;
after forming the quantum dot light-emitting layer and before forming a second electrode, the preparation method may further include: forming a hole transport layer and a hole injection layer on the quantum dot light-emitting layer sequentially; and
the forming a second electrode includes: forming the second electrode on the hole injection layer.

In an exemplary embodiment, a material of the first electrode may be a conductive substrate or a substrate on which a first transparent conductive oxide is deposited, the first transparent conductive oxide may be selected from any one or more of Indium Tin Oxide (ITO), Indium Zinc Oxide (IZO), and F-doped Tin Oxide (FTO); a material of the second electrode may be a metal or a second transparent conductive oxide, the metal may be Mg, Ag, Al and an alloy thereof, the second transparent conductive oxide may be indium zinc oxide, and the second electrode may be formed by evaporation or sputtering.

In an exemplary embodiment, a material of the hole injection layer may be selected from any one or more of poly(3,4-ethylene dioxythiophene)/polystyrene sulfonate, NiO, MoO₃, WoO₃, V₂O₅, CuO, CuS, CuSCN and Cu:NiO; and the hole injection layer may be formed by spin coating, evaporation or inkjet printing.

In an exemplary embodiment, a material of the hole injection layer may be poly(3,4-ethylene dioxythiophene)/polystyrene sulfonate, wherein a film forming temperature of poly 3,4-ethylene dioxythiophene may be 130° C. to 150° C., and a rotating speed of a spin coater at the time of film formation may be 500 rpm to 2500 rpm.

In an exemplary embodiment, a material of the hole transport layer may be selected from any one or more of poly(9,9-dioctylfluorene-CO—N-(4-butylphenyl)diphenylamine) (TFB), polyvinyl carbazole (PVK), N,N′-bis(3-methylphenyl)-N,N′-diphenyl-1,1′-biphenyl-4,4′-diamine (TPD), and 4,4′-bis(9-carbazole)biphenyl (CBP); and the hole transport layer may be formed by spin coating, evaporation or inkjet printing.

In an exemplary embodiment, the electron transport layer may be a zinc oxide nanoparticle thin film or a zinc oxide sol-gel thin film; a material of the zinc oxide nanoparticle thin film may be zinc oxide nanoparticles or doped zinc oxide nanoparticles, and a metal doped in the doped zinc oxide nanoparticles may be selected from any one or more of Mg, In, Al and Ga.

In an exemplary embodiment, a preparation process of the zinc oxide nanoparticle thin film may include: dissolving zinc oxide nanoparticles in an alcohol solvent to obtain an alcohol solution of the zinc oxide nanoparticles, spin coating the alcohol solution of the zinc oxide nanoparticles and heating to form a film;
wherein a temperature of the alcohol solution of the zinc oxide nanoparticles at the time of film formation may be 25° C. to 120° C., and a speed of the spin coating may be 500 rpm to 2500 rpm.

In an exemplary embodiment, a preparation process of the zinc oxide sol-gel thin film may include: dissolving a zinc precursor in a solvent to obtain a solution containing a zinc precursor, spin coating the solution containing the zinc precursor and heating to form a film;
wherein a temperature of the solution containing the zinc precursor at the time of film formation may be 180° C. to 250° C., a speed of the spin coating may be 1000 rpm to 4000 rpm, the zinc precursor may be zinc acetate, and the solvent for dissolving the zinc precursor may be a mixed solvent of ethanolamine and n-butanol.

Other aspects may be understood upon reading and understanding the drawings and detailed description.

### BRIEF DESCRIPTION OF DRAWINGS

Accompanying drawings are used for providing understanding of technical solutions of the present disclosure, and form a part of the specification. They are used for explaining the technical solutions of the present disclosure together with the embodiments of the present disclosure, but do not form a limitation on the technical solutions of the present disclosure.

FIG. 1 is a schematic flowchart of a preparation method for a quantum dot film according to an exemplary embodiment of the present disclosure.

FIG. 2 is a schematic flowchart of another preparation method for a quantum dot film according to an exemplary embodiment of the present disclosure.

FIG. 3 is a schematic diagram of a structure of an upright QLED device according to an exemplary embodiment of the present disclosure.

FIG. 4 is a schematic diagram of a structure of an inverted QLED device according to an exemplary embodiment of the present disclosure.

Meanings of reference signs in the accompanying drawings are as follows:
1—oil-soluble ligand; 2—quantum dot; 3—initial quantum dot film; 4—halogen ion; 5—I⁻; 6—Br⁻; 7—Cl⁻; 100—anode; 200—hole injection layer; 300—hole transport layer; 400—quantum dot light-emitting layer; 500—electron transport layer; and 600—cathode.

### DETAILED DESCRIPTION

Implementations herein may be implemented in multiple different forms. Those of ordinary skills in the art can readily appreciate a fact that the implementations and contents may be varied into various forms without departing from the spirit and scope of the present disclosure. Therefore, the present disclosure should not be explained as being limited to contents described in following implementation modes only. The embodiments in the present disclosure and features in the embodiments may be combined randomly with each other without conflict.

In the accompanying drawings, a size of a constituent element, a thickness of a layer or a region is sometimes exaggerated for clarity. Therefore, any one implementation of the present disclosure is not necessarily limited to dimensions shown in the drawings, and the shapes and sizes of the components in the accompanying drawings do not reflect actual scales. In addition, the accompanying drawings schematically show an ideal example, and any one implementation of the present disclosure is not limited to the shapes, values, or the like shown in the accompanying drawings.

Ordinal numerals such as “first”, “second”, and “third” in the specification are set to avoid confusion of constituent elements, but not to set a limit in quantity.

In the specification, a “film” and a “layer” are interchangeable. For example, a “conductive layer” may be replaced with a “conductive film” sometimes. Similarly, a “quantum dot film” may sometimes be replaced by a “quantum dot layer”.

At the time of synthesizing quantum dots, in order to facilitate the synthesis and dispersion of quantum dots in an organic solvent, it is necessary to select a long-chain organic ligand, such as oleic acid, oleamine, dodecanethiol, etc., as a surface passivation material of the quantum dots, to reduce surface defects of the quantum dots and improve fluorescence properties of the quantum dot materials. However, a long-chain organic ligand has a certain chain length, which, on the one hand, will reduce the transport performance of carriers, and on the other hand, will incur distortion or even entanglement, forming steric hindrance. As a result, the number of ligands which can be introduced to the surface of the quantum dots is limited, the passivation effect is limited, and the ligands cannot completely cover the defects of the surface. Moreover, hanging bonds on the surface of the quantum dots cannot be completely eliminated, and the hanging bonds can easily capture carriers, which can easily cause non-radiation recombination in a device and reduce the light-emitting efficiency.

An embodiment of the present disclosure provides a quantum dot film formed by quantum dots containing a ligand, the ligand being a halogen ion.

In an exemplary embodiment, the ligand may be selected from any one or more of I⁻, Br⁻, and Cl⁻.

In an exemplary embodiment, the ligand may be selected from two or three of I⁻, Br⁻ and Cl⁻.

In an exemplary embodiment, the quantum dot may be selected from any one or more of CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaNk, ZnTe, Si, Ge and C.

In an exemplary embodiment, the quantum dot is a cadmium-free quantum dot.

The ligand on the surface of the quantum dot film in an embodiment of the present disclosure is an inorganic ligand a halogen ion, and defect sites on the surface of the quantum dot which are not passivated by the ligands are occupied by inorganic ligands. Due to the small steric hindrance of the halogen ion, more ligands can be introduced to better eliminate the defects on the surface of the quantum dots, thereby realizing an improvement in the yield of fluorescence quanta of a film layer, and also reducing the Auger recombination center of a device manufactured by the quantum dot film. Moreover, an energy level gradient is formed in the quantum dot film from the surface to the interior of the film layer, which improves the injection of carriers and further improves the efficiency of a quantum dot light-emitting device. In addition, the ligand on the surface of the quantum dot film is an inorganic ligand, which can improve the service life of the quantum dot light-emitting device.

An embodiment of the present disclosure further provides a preparation method for a quantum dot film, including:
S100: preparing an initial quantum dot film by using quantum dots containing an oil-soluble ligand; and
S200: using a solid-state ligand exchange method to perform ligand exchange on the oil-soluble ligand on a surface of the initial quantum dot film by using an organic salt of a halogen, such that the oil-soluble ligand on the surface of the quantum dot film is exchanged into a halogen ion, and subjecting the organic salt of a halogen to a coordination reaction with an unoccupied defect site on the surface of the quantum dot to obtain a quantum dot film with a surface ligand being a halogen ion.

In the preparation method for a quantum dot film according to an embodiment of the present disclosure, after an initial quantum dot film is obtained, an organic salt of a halogen is used to perform ligand exchange on an oil-soluble ligand on the surface of the initial quantum dot film to replace an oil-soluble ligand with poor conductivity on the surface, and the organic salt of a halogen and unoccupied defect sites on the surface of the quantum dot are subjected to a coordination reaction, so that the defect sites on the surface of the quantum dot which are not passivated by the ligands are occupied by more inorganic ligands—halogen ions with small steric hindrance, thus eliminating the defects on the surface of the quantum dot, thereby realizing an improvement in the yield of fluorescence quanta of a film layer, and also reducing the Auger recombination center of a device manufactured by the quantum dot film. Moreover, the preparation method for a quantum dot film according to an embodiment of the present disclosure enables the formation of an energy level gradient in the quantum dot film from the surface to the interior of the film layer, which improves the injection of carriers and further improves the efficiency of a quantum dot light-emitting device. In addition, the ligand on the surface of the quantum dot film is an inorganic ligand, which can improve the service life of the quantum dot light-emitting device.

In an exemplary embodiment, the step S200 may include:
S201: performing ligand exchange on the oil-soluble ligand on the surface of the initial quantum dot film by using an organic salt of a first halogen, such that the oil-soluble ligand on the surface of the quantum dot film is exchanged into a first halogen ion, and subjecting the organic salt of a first halogen to a coordination reaction with an unoccupied defect site on the surface of the quantum dot to obtain a first quantum dot film with a surface ligand being a first halogen ion; and
S202: subjecting an organic salt of a second halogen to a coordination reaction with an unoccupied defect site on a surface of the first quantum dot film to obtain a second quantum dot film with surface ligands being a first halogen ion and a second halogen ion;
wherein a particle size of the first halogen ion is larger than that of the second halogen ion.

In an exemplary embodiment, the step S200 may further include: after the step S202,
S203: subjecting an organic salt of a third halogen to a coordination reaction with an unoccupied defect site on a surface of the second quantum dot film to obtain a third quantum dot film with surface ligands being a first halogen ion, a second halogen ion and a third halogen ion;
wherein a particle size of the second halogen ion is larger than that of the third halogen ion.

In an exemplary embodiment, the first halogen ion may be I⁻, the second halogen ion may be Br⁻, and the third halogen ion may be Cl⁻.

When at least two halogen ions are used for ligand exchange and a coordination reaction, a halogen ion with a larger particle size (larger steric hindrance) is selected for ligand exchange first, and then a halogen ion with a smaller particle size (smaller steric hindrance) is used for ligand exchange. By selecting ligands with different sizes for multiple exchanges and passivations, more halogen ion ligands may be introduced on the surface of the quantum dot film, so that the defect state of the surface of the quantum dot is effectively passivated, thereby improving the device efficiency.

In an exemplary embodiment, the ligand exchange or the coordination reaction may include:
dissolving an organic salt of a halogen in a solvent to prepare an organic salt solution of a halogen;
dropping the organic salt solution of a halogen onto a quantum dot film to be subjected to ligand exchange or a coordination reaction, standing for a first period of time and then spinning dry; or soaking the quantum dot film to be subjected to ligand exchange or a coordination reaction in the organic salt solution of a halogen, standing for a second period of time, and then taking the quantum dot film out from the organic salt solution of a halogen and spinning dry; and
cleaning a surface of the spinning-dried quantum film with a same solvent as that used for formulating the organic salt solution of a halogen.

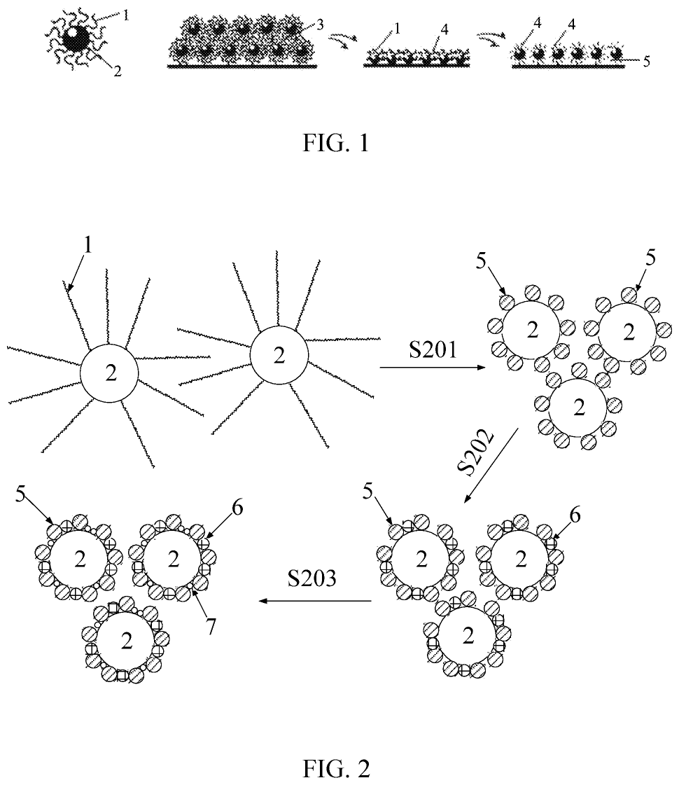

FIG. 1 is a schematic flowchart of a preparation method for a quantum dot film according to an exemplary embodiment of the present disclosure. As shown in FIG. 1, the preparation method may include:
S100: preparing an initial quantum dot film 3 by using quantum dots 2 containing an oil-soluble ligand 1;
S200-1: dissolving an organic salt of a halogen in a solvent to prepare an organic salt solution of a halogen, dropping the organic salt solution of a halogen onto the initial quantum dot film 3, standing, spinning dry, subjecting halogen ions 4 in the organic salt solution of a halogen to ligand exchange with the oil-soluble ligand 1 on the surface of the initial quantum dot film 3, and subjecting the organic salt of a halogen to a coordination reaction with unoccupied defect sites on the surface of the initial quantum dot film 3; and
S200-2: cleaning a surface of the spinning-dried quantum film with a same solvent as that used for formulating the organic salt solution of a halogen, so that impurities (including the organic salt of a halogen that has not been reacted, the oil-soluble ligands resulting from the exchange, etc.) on the surface of the quantum dot film are cleaned off, obtaining a quantum dot film 5 with the ligand on the surface being a halogen ion.

It should be understood that in the preparation method for a quantum dot film according to an embodiment of the present disclosure, halogen ions may not exchange 100% of the oil-soluble ligands, so the resultant quantum film may contain a small amount of oil-soluble ligands, but the ligands contained therein are substantially halogen ion ligands.

FIG. 2 is a schematic flowchart of another preparation method for a quantum dot film according to an exemplary embodiment of the present disclosure. As shown in FIG. 2, in an exemplary embodiment, the preparation method may include:
S100: preparing an initial quantum dot film by using quantum dots 2 containing an oil-soluble ligand 1;
S201: performing ligand exchange on the oil-soluble ligand 1 on the surface of the initial quantum dot film by using an organic salt of iodine, such that the oil-soluble ligand 1 on the surface of the quantum dot film is exchanged into I⁻ 5, and subjecting the organic salt of iodine to a coordination reaction with an unoccupied defect site on the surface of the quantum dot to obtain a first quantum dot film with a surface ligand being I⁻ 5;
S202: subjecting an organic salt of bromine to a coordination reaction with an unoccupied defect site on a surface of the first quantum dot film to obtain a second quantum dot film with surface ligands being I⁻ 5 and Br⁻ 6; and
S203: subjecting an organic salt of chlorine to a coordination reaction with an unoccupied defect site on a surface of the second quantum dot film to obtain a third quantum dot film with surface ligands being I⁻ 5, Br⁻ 6 and Cl⁻ 7.

In an exemplary embodiment, a concentration of the organic salt solution of a halogen may be 2 mg/mL to 50 mg/ml.

In an exemplary embodiment, the organic salt of a halogen may be selected from any one or more of tetrabutyl ammonium halide, tetrapropyl ammonium halide, and tetrapentyl ammonium halide; and the halogen in the organic salt of a halogen is I, Br or Cl.

In an exemplary embodiment, the solvent may be any one or more of deionized water, acetonitrile, methanol and ethanol.

In an exemplary embodiment, the first period of time may be 30 seconds to 90 seconds.

In an exemplary embodiment, the second period of time may be 10 seconds to 120 seconds.

In an exemplary embodiment, the quantum dot may be selected from any one or more of CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaNk, ZnTe, Si, Ge and C.

In an exemplary embodiment, the quantum dot is a cadmium-free quantum dot.

An embodiment of the present disclosure further provides a photoelectric device, which may be any one of a quantum dot light-emitting device, a photodetector, a photovoltaic device, a light-responsive transistor and a field-responsive transistor, the photoelectric device including the quantum dot film described above.

In an exemplary embodiment, the photoelectric device is a quantum dot light-emitting device, including an anode, a cathode, and a quantum dot light-emitting layer disposed between the anode and the cathode, the quantum dot light-emitting layer being the quantum dot film described above.

An embodiment of the present disclosure further provides a display apparatus, including a plurality of quantum dot light-emitting devices, a light-emitting layer of the quantum dot light-emitting device being the quantum dot film described above.

An embodiment of the present disclosure further provides a display apparatus, including a plurality of quantum dot light-emitting devices, a light-emitting layer of the quantum dot light-emitting device being the quantum dot film described above. The display apparatus may be any product or component with a display function, such as a mobile phone, a tablet computer, a television, a display, a laptop computer, a digital photo frame, a navigator, a vehicle-mounted display, a smart watch, a smart bracelet, etc.

An embodiment of the present disclosure further provides a preparation method for a quantum dot light-emitting device, including:
forming a first electrode;
forming a quantum dot light-emitting layer, the quantum dot light-emitting layer being a quantum dot film formed by quantum dots containing a ligand, the ligand being a halogen ion; and
forming a second electrode.

In an exemplary embodiment, the forming a quantum dot light-emitting layer may include:
S100: preparing an initial quantum dot film by using quantum dots containing an oil-soluble ligand; and
S200: using a solid-state ligand exchange method to perform ligand exchange on the oil-soluble ligand on a surface of the initial quantum dot film by using an organic salt of a halogen, such that the oil-soluble ligand on the surface of the quantum dot film is exchanged into a halogen ion, and subjecting the organic salt of a halogen to a coordination reaction with an unoccupied defect site on the surface of the quantum dot to obtain a quantum dot film with a surface ligand being a halogen ion, thus obtaining a quantum dot light-emitting layer.

In an exemplary embodiment, the step S200 may include:
S201: performing ligand exchange on the oil-soluble ligand on the surface of the initial quantum dot film by using an organic salt of a first halogen, such that the oil-soluble ligand on the surface of the quantum dot film is exchanged into a first halogen ion, and subjecting the organic salt of a first halogen to a coordination reaction with an unoccupied defect site on the surface of the quantum dot to obtain a first quantum dot film with a surface ligand being a first halogen ion; and
S202: subjecting an organic salt of a second halogen to a coordination reaction with an unoccupied defect site on a surface of the first quantum dot film to obtain a second quantum dot film with surface ligands being a first halogen ion and a second halogen ion;
wherein a particle size of the first halogen ion is larger than that of the second halogen ion.

In an exemplary embodiment, the step S200 may further include: after the step S202,
S203: subjecting an organic salt of a third halogen to a coordination reaction with an unoccupied defect site on a surface of the second quantum dot film to obtain a third quantum dot film with surface ligands being a first halogen ion, a second halogen ion and a third halogen ion;
wherein a particle size of the second halogen ion is larger than that of the third halogen ion.

In an exemplary embodiment, the first halogen ion may be I⁻, the second halogen ion may be Br⁻, and the third halogen ion may be Cl⁻.

In an exemplary embodiment, the ligand exchange or the coordination reaction may include:
dissolving an organic salt of a halogen in a solvent to prepare an organic salt solution of a halogen;
dropping the organic salt solution of a halogen onto a quantum dot film to be subjected to ligand exchange or a coordination reaction, standing for a first period of time and then spinning dry; or soaking the quantum dot film to be subjected to ligand exchange or a coordination reaction in the organic salt solution of a halogen, standing for a second period of time, and then taking the quantum dot film out from the organic salt solution of a halogen and spinning dry; and
cleaning a surface of the spinning-dried quantum film with a same solvent as that used for formulating the organic salt solution of a halogen.

In an exemplary embodiment, a concentration of the organic salt solution of a halogen may be 2 mg/mL to 50 mg/ml.

In an exemplary embodiment, the organic salt of a halogen may be selected from any one or more of tetrabutyl ammonium halide, tetrapropyl ammonium halide, and tetrapentyl ammonium halide; and the halogen in the organic salt of a halogen is I, Br or Cl.

In an exemplary embodiment, the solvent may be any one or more of deionized water, acetonitrile, methanol and ethanol.

In an exemplary embodiment, the first period of time may be 30 seconds to 90 seconds.

In an exemplary embodiment, the second period of time may be 10 seconds to 120 seconds.

In an exemplary embodiment, the quantum dot may be selected from any one or more of CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaNk, ZnTe, Si, Ge and C; and the initial quantum dot film may be formed by spin coating, evaporation or inkjet printing.

In an exemplary embodiment, the quantum dot light-emitting device may be in an upright structure or an inverted structure, the upright structure includes an upright top emission structure and an upright bottom emission structure, and the inverted structure includes an inverted top emission structure and an inverted bottom emission structure.

In an exemplary embodiment, the quantum dot light-emitting device is in an upright structure where the first electrode is an anode and the second electrode is a cathode;
after forming the first electrode and before forming a quantum dot light-emitting layer, the preparation method may further include: forming a hole injection layer and a hole transport layer on the first electrode sequentially;
the forming a quantum dot light-emitting layer includes: forming the quantum dot light-emitting layer on the hole transport layer;
after forming the quantum dot light-emitting layer and before forming a second electrode, the preparation method may further include: forming an electron transport layer on the quantum dot light-emitting layer; and
the forming the second electrode includes: forming the second electrode on the electron transport layer.

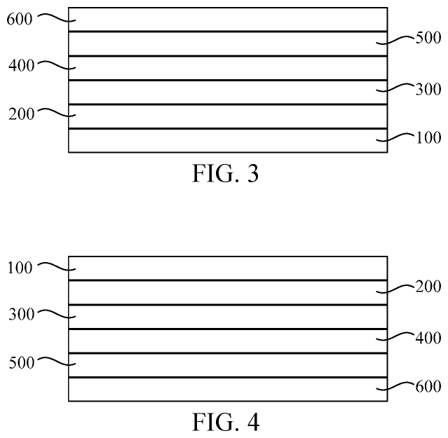

FIG. 3 is a schematic diagram of a structure of an upright QLED device according to an exemplary embodiment of the present disclosure. As shown in FIG. 3, the QLED device in an upright structure may include: an anode 100, a hole injection layer 200 disposed on the anode 100, a hole transport layer 300 disposed on a side of the hole injection layer 200 away from the anode 100, a quantum dot light-emitting layer 400 disposed on a side of the hole transport layer 300 away from the anode 100, an electron transport layer 500 disposed on a side of the quantum dot light-emitting layer 400 away from the anode 100, and a cathode 600 disposed on a side of the electron transport layer 500 away from the anode 100.

In an exemplary embodiment, in the QLED device in an upright structure,
the anode 100 may be a bottom emission substrate conductive glass or a common glass substrate on which a conductive layer is deposited, and the conductive layer may be formed of a conductive transparent material such as Indium Tin Oxide (ITO), Indium Zinc Oxide (IZO), F-doped Tin Oxide (FTO);
the hole injection layer 200 may be prepared by spin coating, evaporation, inkjet printing or the like; wherein PEDOT:PSS 4083 (poly(3,4-ethylene dioxythiophene)/polystyrene sulfonate) or other commercially available compounds, etc. suitable for forming hole injection layers, such as NiO, MoO₃, WoO₃, V₂O₅, CuO, CuS, CuSCN, Cu:NiO and the like, may be selected for an organic hole injection layer; a film forming temperature of the PEDOT may be 130° C. to 150° C., and a rotating speed of a spin coater at the time of film formation may be set to 500 rpm to 2500 rpm to adjust a thickness of a film layer;
the hole transport layer 300 may be prepared by spin coating, evaporation, inkjet printing or the like, and a material of the hole transport layer may be selected from mature commercially available materials such as poly(9,9-dioctylfluorene-CO—N-(4-butylphenyl)diphenylamine) (TFB), polyvinyl carb azole (PVK), N,N′-bis(3-methylphenyl)-N,N′-diphenyl-1,1′-biphenyl-4,4′-diamine (TPD), 4,4′-bis(9-carbazole)biphenyl (CBP);
the quantum dot light-emitting layer 400 may be prepared by spin coating, evaporation, inkjet printing, or the like, and the quantum dots for preparing the quantum dot light-emitting layer may include CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaNk, ZnTe, Si, Ge, C and other nano-scale materials having the above components, such as nanorods and nano-sheets;
taking a quantum dot light-emitting layer synthesized by CdSe quantum dots as an example, a specific synthesis method is: in an inert gas and at about 100° C., dissolving selenium powder in octadecene to obtain a selenium solution; adding CdO and an oleic acid into octadecene and heating to about 280° C. to obtain a precursor solution of cadmium; adding the selenium solution into the precursor solution of cadmium, cooling down to about 250° C. for reaction, cooling down to room temperature after the completion of the reaction, extracting with methanol-hexane to remove unreacted precursor, precipitating with ethanol and dissolving in octane to obtain a CdSe quantum dot solution, and forming a film by spin coating (or by stamping, printing, EFI printing and the like);
a material of the electron transport layer 500 may be selected from any one or more of alumina, barium fluoride, titanium dioxide, zinc sulfide, zirconia, zinc selenide, magnesium oxide, zinc oxide, yttrium oxide and aluminum fluoride; for example, a zinc oxide nanoparticle thin film, a zinc oxide sol-gel thin film or the like may be selected as the electron transport layer 500;
(a) preparation of the zinc oxide nanoparticle thin film: for example, a solution obtained by dissolving 90 μL to 120 μL zinc oxide nanoparticles with a concentration of 10 mg/mL to 30 mg/mL in an alcohol solvent (e.g. methanol, ethanol, isopropanol, etc.) is dropped onto the quantum dot light-emitting layer for spin coating to form a film by a spin coater at a rotating speed set to 500 rpm to 2500 rpm, and the film is formed at room temperature or under heating (a temperature may be 25° C. to 120° C.) to adjust a thickness of the zinc oxide nanoparticle thin film;
(b) preparation of the zinc oxide sol-gel thin film: 2 g zinc acetate is added into a mixed solvent of 10 mL ethanolamine and n-butanol, spin coating is performed to form a film, with a rotating speed of the spin coater set to 1000 rpm to 4000 rpm, and the film is formed under heating on a hot table at 180° C. to 250° C.;
the material of the electron transport layer 500 may also be ion-doped zinc oxide nanoparticles, such as Mg, In, Al or Ga doped zinc oxide nanoparticles and the like; and
the cathode 600 may be prepared by evaporation or sputtering and may be a metal film (e.g. an Al film) or an IZO film.

In an exemplary embodiment, the quantum dot light-emitting device is in an inverted structure where the first electrode is a cathode and the second electrode is an anode;
after forming the first electrode and before forming a quantum dot light-emitting layer, the preparation method may further include: forming an electron transport layer on the first electrode;
the forming a quantum dot light-emitting layer includes: forming the quantum dot light-emitting layer on the electron transport layer;
after forming the quantum dot light-emitting layer and before forming a second electrode, the preparation method may further include: forming a hole transport layer and a hole injection layer on the quantum dot light-emitting layer sequentially; and
the forming a second electrode includes: forming the second electrode on the hole injection layer.

FIG. 4 is a schematic diagram of a structure of an inverted QLED device according to an exemplary embodiment of the present disclosure. As shown in FIG. 4, the QLED device in an inverted structure may include: a cathode 600, an electron transport layer 500 disposed on the cathode 600, a quantum dot light-emitting layer 400 disposed on a side of the electron transport layer 500 away from the cathode 600, a hole transport layer 300 disposed on a side of the quantum dot light-emitting layer 400 away from the cathode 600, a hole injection layer 200 disposed on a side of the hole transport layer 300 away from the cathode 600, and an anode 100 disposed on a side of the hole injection layer 200 away from the cathode 600.

In an exemplary embodiment, in the QLED device in an inverted structure,
the cathode 600 may be a bottom emission substrate conductive glass or a common glass substrate on which a conductive layer is deposited, and the conductive layer may be formed of a conductive transparent material such as Indium Tin Oxide (ITO), Indium Zinc Oxide (IZO), F-doped Tin Oxide (FTO);
the anode 100 may be prepared by evaporation or sputtering and may be a metal film (e.g., an Al film) or an IZO film; and
the hole injection layer 200, the hole transport layer 300, the quantum dot light-emitting layer 400, and the electron transport layer 500 may be prepared by a same material and a same method as the material and method for the QLED device in an upright structure.

An exemplary embodiment of the present disclosure provides a preparation method for a QLED device in the upright structure shown in FIG. 3, including:
(1) preparation of an anode:
using a bottom emission substrate conductive glass as an anode: cleaning the bottom emission substrate conductive glass by isopropanol, water and acetone respectively and treating under UV for 5 min to 10 min; or,
using a common glass substrate on which a conductive layer is deposited as an anode, wherein the conductive layer may be formed of a conductive transparent material such as ITO, IZO and FTO;
(2) preparation of a hole injection layer on the anode: on the anode, preparing a hole injection layer by spin coating, evaporation, inkjet printing or the like; wherein PEDOT:PSS 4083 (poly 3,4-ethylene dioxythiophene/polystyrene sulfonate) or other commercially available compounds, etc. suitable for forming hole injection layers, such as NiO, MoO₃, WoO₃, V₂O₅, CuO, CuS, CuSCN, Cu:NiO and the like, may be selected for an organic hole injection layer; a film forming temperature of the PEDOT may be 130° C. to 150° C., and a rotating speed of a spin coater at the time of film formation may be set to 500 rpm to 2500 rpm to adjust a thickness of a film layer;
(3) preparation of a hole transport layer on the hole injection layer: on the hole injection layer, preparing a hole transport layer by spin coating, evaporation, inkjet printing, or the like, wherein a material of the hole transport layer may be selected from mature commercially available materials such as TFB, PVK, TPD, CBP;
(4) preparation of an initial quantum dot film on the hole transport layer: on the hole transport layer, preparing an initial quantum dot film by spin coating, evaporation, inkjet printing or the like, wherein the quantum dots for preparing the initial quantum dot film may include CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaNk, ZnTe, Si, Ge, C and other nano-scale materials having the above components, such as nanorods and nano-sheets;
wherein taking an initial quantum dot film synthesized by CdSe quantum dots as an example, a specific synthesis method is, for example: in an inert gas and at about 100° C., dissolving selenium powder in octadecene to obtain a selenium solution; adding CdO and an oleic acid into octadecene and heating to about 280° C. to obtain a precursor solution of cadmium; adding the selenium solution into the precursor solution of cadmium, cooling down to about 250° C. for reaction, cooling down to room temperature after the completion of the reaction, extracting with methanol-hexane to remove unreacted precursor, precipitating with ethanol and dissolving in octane to obtain a CdSe quantum dot solution, and forming a film by spin coating (or by stamping, printing, EFI printing and the like);
(5) subjecting the initial quantum dot film to ligand exchange and a coordination reaction to obtain a quantum dot light-emitting layer:
(a) ligand exchange and coordination reaction of iodine ions: preparing a methanol solution of tetrabutyl ammonium iodide with a concentration of 2 mg/mL to 50 mg/ml, dropping the methanol solution of tetrabutyl ammonium iodide onto the quantum dot light-emitting layer obtained in step (4), standing for 60 s, spinning dry, and repeatedly cleaning the surface of the quantum dot film with methanol to remove impurities on the surface of the quantum dot film; (b) coordination reaction of bromine ions: preparing a methanol solution of tetrabutyl ammonium bromide with a concentration of 2 mg/mL to 50 mg/ml, dropping the methanol solution of tetrabutyl ammonium bromide onto the quantum dot film obtained in step (a), standing for 60 s, spinning dry, and repeatedly cleaning the surface of the quantum dot film with methanol to remove impurities on the surface of the quantum dot film; and (c) coordination reaction of chloride ions: preparing a methanol solution of tetrabutyl ammonium chloride with a concentration of 2 mg/mL to 50 mg/ml, dropping the methanol solution of tetrabutyl ammonium chloride onto the quantum dot film obtained in step (b), standing for 60 s, spinning dry, and repeatedly cleaning the surface of the thin film with methanol to remove impurities on the surface of the quantum dot film; wherein after the above acts, a quantum dot light-emitting layer after ligand exchange is obtained;
(6) preparation of an electron transport layer on the quantum dot light-emitting layer: preparing an electron transport layer on the quantum dot light-emitting layer obtained in step (5), wherein a zinc oxide nanoparticle thin film, a zinc oxide sol-gel thin film or the like may be selected as the electron transport layer;
(a) preparation of the zinc oxide nanoparticle thin film: for example, dropping a solution obtained by dissolving 90 μL to 120 μL zinc oxide nanoparticles with a concentration of 10 mg/mL to 30 mg/mL in an alcohol solvent (e.g. methanol, ethanol, isopropanol, etc.) onto the quantum dot light-emitting layer obtained in step (5) for spin coating to form a film by a spin coater at a rotating speed set to 500 rpm to 2500 rpm, wherein the film is formed at room temperature or under heating (a temperature may be 25° C. to 120° C.) to adjust a thickness of the zinc oxide nanoparticle thin film;
(b) preparation of the zinc oxide sol-gel thin film: adding 2 g zinc acetate into a mixed solvent of 10 mL ethanolamine and n-butanol, spin coating to form a film, with a rotating speed of the spin coater set to 1000 rpm to 4000 rpm, wherein the film is formed under heating on a hot table at 180° C. to 250° C.;
the material of the electron transport layer may also be ion-doped zinc oxide nanoparticles, such as Mg, In, Al or Ga doped zinc oxide nanoparticles and the like; and
(7) preparation of a cathode on the electron transport layer: introducing an anode material to the electron transport layer to prepare a cathode, e.g., evaporating an Al film or sputtering an IZO film, to prepare a QLED device.

An exemplary embodiment of the present disclosure provides a preparation method for a QLED device in the inverted structure shown in FIG. 4, including:
(1) preparation of a cathode:
using a bottom emission substrate conductive glass as a cathode: cleaning the bottom emission substrate conductive glass by isopropanol, water and acetone respectively and treating under UV for 5 min to 10 min; or,
using a common glass substrate on which a conductive layer is deposited as a cathode, wherein the conductive layer may be formed of a conductive transparent material such as Indium Tin Oxide (ITO), Indium Zinc Oxide (IZO), and F-doped Tin Oxide (FTO);
(2) preparation of an electron transport layer on the cathode: preparing an electron transport layer on the cathode, wherein a zinc oxide nanoparticle thin film, a zinc oxide sol-gel thin film or the like may be selected as the electron transport layer;
(a) preparation of the zinc oxide nanoparticle thin film: for example, dropping a solution obtained by dissolving 90 μL to 120 μL zinc oxide nanoparticles with a concentration of 10 mg/mL to 30 mg/mL in an alcohol solvent (e.g. methanol, ethanol, isopropanol, etc.) onto the cathode for spin coating to form a film by a spin coater at a rotating speed set to 500 rpm to 2500 rpm, wherein the film is formed at room temperature or under heating (a temperature may be 25° C. to 120° C.) to adjust a thickness of the zinc oxide nanoparticle thin film;
(b) preparation of the zinc oxide sol-gel thin film: adding 2 g zinc acetate into a mixed solvent of 10 mL ethanolamine and n-butanol, spin coating to form a film, with a rotating speed of the spin coater set to 1000 rpm to 4000 rpm, wherein the film is formed under heating on a hot table at 180° C. to 250° C.;
the material of the electron transport layer may also be ion-doped zinc oxide nanoparticles, such as Mg, In, Al or Ga doped zinc oxide nanoparticles and the like;
(3) preparation of an initial quantum dot film on the electron transport layer: on the electron transport layer, preparing an initial quantum dot film by spin coating, evaporation, inkjet printing or the like, wherein the quantum dots for preparing the initial quantum dot film may include CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaNk, ZnTe, Si, Ge, C and other nano-scale materials having the above components, such as nanorods and nano-sheets;
wherein taking an initial quantum dot film synthesized by CdSe quantum dots as an example, a specific synthesis method is, for example: in an inert gas and at about 100° C., dissolving selenium powder in octadecene to obtain a selenium solution; adding CdO and an oleic acid into octadecene and heating to about 280° C. to obtain a precursor solution of cadmium; adding the selenium solution into the precursor solution of cadmium, cooling down to about 250° C. for reaction, cooling down to room temperature after the completion of the reaction, extracting with methanol-hexane to remove unreacted precursor, precipitating with ethanol and dissolving in octane to obtain a CdSe quantum dot solution, and forming a film by spin coating (or by stamping, printing, EFI printing and the like);
(4) subjecting the initial quantum dot film to ligand exchange and a coordination reaction to obtain a quantum dot light-emitting layer:
(a) ligand exchange and coordination reaction of iodine ions: preparing a methanol solution of tetrabutyl ammonium iodide with a concentration of 2 mg/mL to 50 mg/ml, dropping the methanol solution of tetrabutyl ammonium iodide onto the quantum dot light-emitting layer obtained in step (3), standing for 60 s, spinning dry, and repeatedly cleaning the surface of the quantum dot film with methanol to remove impurities on the surface of the quantum dot film; (b) coordination reaction of bromine ions: preparing a methanol solution of tetrabutyl ammonium bromide with a concentration of 2 mg/mL to 50 mg/ml, dropping the methanol solution of tetrabutyl ammonium bromide onto the quantum dot film obtained in step (a), standing for 60 s, spinning dry, and repeatedly cleaning the surface of the quantum dot film with methanol to remove impurities on the surface of the quantum dot film; and (c) coordination reaction of chloride ions: preparing a methanol solution of tetrabutyl ammonium chloride with a concentration of 2 mg/mL to 50 mg/ml, dropping the methanol solution of tetrabutyl ammonium chloride onto the quantum dot film obtained in step (b), standing for 60 s, spinning dry, and repeatedly cleaning the surface of the thin film with methanol to remove impurities on the surface of the quantum dot film; wherein after the above acts, a quantum dot light-emitting layer after ligand exchange is obtained;
(5) preparation of a hole transport layer on the quantum dot light-emitting layer: on the quantum dot light-emitting layer, preparing a hole transport layer by spin coating, evaporation, inkjet printing, or the like, wherein a material of the hole transport layer may be selected from mature commercially available materials such as TFB, PVK, TPD, CBP;
(6) preparation of a hole injection layer on the hole transport layer: on the hole transport layer, preparing a hole injection layer by spin coating, evaporation, inkjet printing or the like; wherein PEDOT:PSS 4083 (poly 3,4-ethylene dioxythiophene/polystyrene sulfonate) or other commercially available compounds, etc. suitable for forming hole injection layers, such as NiO, MoO₃, WoO₃, V₂O₅, CuO, CuS, CuSCN, Cu:NiO and the like, may be selected for an organic hole injection layer; a film forming temperature of the PEDOT may be 130° C. to 150° C., and a rotating speed of a spin coater at the time of film formation may be set to 500 rpm to 2500 rpm to adjust a thickness of a film layer; and
(7) preparation of an anode on the hole injection layer: introducing an electrode material to the hole injection layer to prepare an anode, e.g., evaporating an Al film or sputtering an IZO film, to prepare a QLED device.

Although the implementation modes disclosed in the present disclosure are as above, the described contents are only implementation modes used for facilitating understanding the present disclosure and are not intended to limit the present disclosure. Any person skilled in the art may make any modification and change in the forms and details of the implementations without departing from the essence and scope of the present disclosure. However, the scope of patent protection of the present disclosure should still be subject to the scope defined by the attached claims.

1. A quantum dot film, formed by quantum dots containing a ligand, the ligand being a halogen ion.

2. The quantum dot film according to claim 1, wherein the ligand is selected from any one or more of I⁻, Br⁻, and Cl⁻.

3. The quantum dot film according to claim 2, wherein the ligand is selected from two or three of I⁻, Br⁻ and Cl⁻.

4. The quantum dot film according to claim 1, wherein the quantum dot is selected from any one or more of CdS, CdSe, CdTe, ZnSe, InP, PbS, CuInS₂, ZnO, CsPbCl₃, CsPbBr₃, CsPhI₃, CdS/ZnS, CdSe/ZnS, ZnSe, InP/ZnS, PbS/ZnS, InAs, InGaAs, InGaN, GaNk, ZnTe, Si, Ge and C.

5. A photoelectric device, which is any one of a quantum dot light-emitting device, a photodetector, a photovoltaic device, a light-responsive transistor and a field-responsive transistor, the photoelectric device comprising the quantum dot film according to claim 1.

6. The photoelectric device according to claim 5, wherein the photoelectric device is a quantum dot light-emitting device, comprising an anode, a cathode, and a quantum dot light-emitting layer disposed between the anode and the cathode, the quantum dot light-emitting layer being the quantum dot film.

7. A display apparatus, comprising a plurality of photoelectric devices according to claim 6.

8. A preparation method for a quantum dot film, comprising:
S100: preparing an initial quantum dot film by using quantum dots containing an oil-soluble ligand; and
S200: using a solid-state ligand exchange method to perform ligand exchange on the oil-soluble ligand on a surface of the initial quantum dot film by using an organic salt of a halogen, such that the oil-soluble ligand on the surface of the quantum dot film is exchanged into a halogen ion, and subjecting the organic salt of a halogen to a coordination reaction with an unoccupied defect site on the surface of the quantum dot to obtain a quantum dot film with a surface ligand being a halogen ion.

9. The preparation method according to claim 8, wherein the step S200 comprises:
S201: performing ligand exchange on the oil-soluble ligand on the surface of the initial quantum dot film by using an organic salt of a first halogen, such that the oil-soluble ligand on the surface of the quantum dot film is exchanged into a first halogen ion, and subjecting the organic salt of a first halogen to a coordination reaction with an unoccupied defect site on the surface of the quantum dot to obtain a first quantum dot film with a surface ligand being a first halogen ion; and
S202: subjecting an organic salt of a second halogen to a coordination reaction with an unoccupied defect site on a surface of the first quantum dot film to obtain a second quantum dot film with surface ligands being a first halogen ion and a second halogen ion;
wherein a particle size of the first halogen ion is larger than that of the second halogen ion.

10. The preparation method according to claim 9, wherein the step S200 further comprises: after the step S202,
S203: subjecting an organic salt of a third halogen to a coordination reaction with an unoccupied defect site on a surface of the second quantum dot film to obtain a third quantum dot film with surface ligands being a first halogen ion, a second halogen ion and a third halogen ion;
wherein a particle size of the second halogen ion is larger than that of the third halogen ion.

11. The preparation method according to claim 10, wherein the first halogen ion is I⁻, the second halogen ion is Br⁻, and the third halogen ion is Cl⁻.

12. The preparation method according to claim 8, wherein the ligand exchange or the coordination reaction comprises:
dissolving an organic salt of a halogen in a solvent to prepare an organic salt solution of a halogen;
dropping the organic salt solution of a halogen onto a quantum dot film to be subjected to a ligand exchange or a coordination reaction, standing for a first period of time and then spinning dry; or soaking the quantum dot film to be subjected to a ligand exchange or a coordination reaction in the organic salt solution of a halogen, standing for a second period of time, and then taking the quantum dot film out from the organic salt solution of a halogen and spinning dry; and
cleaning a surface of the spinning-dried quantum film with a same solvent as that used for formulating the organic salt solution of a halogen.

13. (canceled)

14. The preparation method according to claim 8, wherein the organic salt of a halogen is selected from any one or more of tetrabutyl ammonium halide, tetrapropyl ammonium halide, and tetrapentyl ammonium halide; and the halogen in the organic salt of a halogen is I, Br or Cl.

15. The preparation method according to claim 12, wherein the solvent is any one or more of deionized water, acetonitrile, methanol and ethanol.

16-17. (canceled)

18. A preparation method for a quantum dot light-emitting device, comprising:
forming a first electrode;
forming a quantum dot light-emitting layer, the quantum dot light-emitting layer being a quantum dot film formed by quantum dots containing a ligand, the ligand being a halogen ion; and
forming a second electrode.

19. The preparation method according to claim 18, wherein the forming a quantum dot light-emitting layer comprises:
S100: preparing an initial quantum dot film by using quantum dots containing an oil-soluble ligand; and
S200: using a solid-state ligand exchange method to perform ligand exchange on the oil-soluble ligand on a surface of the initial quantum dot film by using an organic salt of a halogen, such that the oil-soluble ligand on the surface of the quantum dot film is exchanged into a halogen ion, and subjecting the organic salt of a halogen to a coordination reaction with an unoccupied defect site on the surface of the quantum dot to obtain a quantum dot film with a surface ligand being a halogen ion, thus obtaining a quantum dot light-emitting layer.

20. The preparation method according to claim 19, wherein the step S200 comprises:
S201: performing ligand exchange on the oil-soluble ligand on the surface of the initial quantum dot film by using an organic salt of a first halogen, such that the oil-soluble ligand on the surface of the quantum dot film is exchanged into a first halogen ion, and subjecting the organic salt of a first halogen to a coordination reaction with an unoccupied defect site on the surface of the quantum dot to obtain a first quantum dot film with a surface ligand being a first halogen ion; and
S202: subjecting an organic salt of a second halogen to a coordination reaction with an unoccupied defect site on a surface of the first quantum dot film to obtain a second quantum dot film with surface ligands being a first halogen ion and a second halogen ion;
wherein a particle size of the first halogen ion is larger than that of the second halogen ion.

21. The preparation method according to claim 20, wherein the step S200 further comprises: after the step S202,
S203: subjecting an organic salt of a third halogen to a coordination reaction with an unoccupied defect site on a surface of the second quantum dot film to obtain a third quantum dot film with surface ligands being a first halogen ion, a second halogen ion and a third halogen ion;
wherein a particle size of the second halogen ion is larger than that of the third halogen ion.

22. The preparation method according to claim 21, wherein the first halogen ion is I⁻, the second halogen ion is Br⁻, and the third halogen ion is Cl⁻.

23. The preparation method according to claim 19, wherein the ligand exchange or the coordination reaction comprises:
dissolving an organic salt of a halogen in a solvent to prepare an organic salt solution of a halogen;
dropping the organic salt solution of a halogen onto a quantum dot film to be subjected to ligand exchange or a coordination reaction, standing for a first period of time and then spinning dry; or soaking the quantum dot film to be subjected to ligand exchange or a coordination reaction in the organic salt solution of a halogen, standing for a second period of time, and then taking the quantum dot film out from the organic salt solution of a halogen and spinning dry; and
cleaning a surface of the spinning-dried quantum film with a same solvent as that used for formulating the organic salt solution of a halogen.

24-38. (canceled)
